(19) United States
(12) Patent Application Publication
(10) Pub. No.: US 2025/0125207 A1
(43) Pub. Date: Apr. 17, 2025

(54) SEMICONDUCTOR MODULE AND MANUFACTURING METHOD THEREFOR

(71) Applicant: FUJI ELECTRIC CO., LTD., Kawasaki-shi (JP)

(72) Inventor: Toshio DENTA, Matsumoto-city (JP)

(73) Assignee: FUJI ELECTRIC CO., LTD., Kawasaki-shi (JP)

(21) Appl. No.: 18/816,224

(22) Filed: Aug. 27, 2024

(30) Foreign Application Priority Data
Oct. 13, 2023 (JP) 2023-177733

(51) Int. Cl. H01L 23/31; H01L 23/00; H01L 23/29; H01L 23/495; H01L 23/538; H01L 25/18

(52) U.S. Cl. CPC H01L 23/3121; H01L 23/295; H01L 23/49524; H01L 23/5386; H01L 24/32; H01L 24/48; H01L 25/18; H01L 2224/32137; H01L 2224/32225; H01L 2224/48111; H01L 2224/48135; H01L 2924/18301; H01L 2924/186

(57) ABSTRACT

A semiconductor module includes: a substrate for mounting a semiconductor element; a frame-shaped housing that surrounds the substrate; a lead terminal that passes through the housing from an inside to an outside of the housing; and a bonding wire configured to electrically connect the semiconductor element to the lead terminal within the housing. The lead terminal has a pad disposed in the housing. The housing has a first surface that is joined to the pad, and a second surface that is joined to the substrate with an adhesive agent, the second surface facing in a direction opposite to the first surface. The inner peripheral surface of the housing has a groove that extends over the entire range from the first surface to the second surface, the groove extending from the substrate toward the pad.

### CROSS REFERENCE TO RELATED APPLICATION

This application is based on, and claims priority from, Japanese Patent Application No. 2023-177733, filed Oct. 13, 2023, the entire content of which is incorporated herein by reference.

### BACKGROUND OF THE INVENTION

### Field of the Invention

The present invention relates to a semiconductor module and to a method of manufacturing a semiconductor module.

### Description of Related Art

Semiconductor modules, as typified by power semiconductor modules, generally include a substrate for mounting semiconductor elements, a resin housing to house the semiconductor elements, and a plurality of lead terminals to be electrically connected to the semiconductor elements through bonding wires. For example, in Japanese Patent Application Laid-Open Publication No. 2015-201611 (Patent Document 1), Japanese Patent Application Laid-Open Publication No. 2023-31941 (Patent Document 2), and Japanese Patent Application Laid-Open Publication No. 2016-111028 (Patent Document 3), a plurality of lead terminals are joined to a housing by insert molding.

A housing formed by insert molding as described above may leave a gap between a pad of a lead terminal and the housing due to poor contact between the lead terminal and the housing. If such a gap exists, when ultrasonic wire bonding is performed on the pad of the lead terminal, resonance of the pad causes transmission loss of ultrasonic waves, resulting in decrease in wire bonding joining ability.

To solve this problem, a possible solution is to fill the gap between the pad of the lead terminal and the housing with an adhesive agent. Configurations described in Patent Documents 1 to 3, however, require a separate step for this solution during the manufacture of semiconductor modules, complicating the manufacturing process.

### SUMMARY

In view of the above circumstances, it is an object of one aspect of the present disclosure to easily manufacture a semiconductor module with excellent reliability.

To solve the above problem, a semiconductor module according to an aspect of the present disclosure includes: a substrate for mounting a semiconductor element; a frame-shaped housing that surrounds the substrate; a lead terminal that passes through the housing from an inside to an outside of the housing; and a bonding wire configured to electrically connect the semiconductor element to the lead terminal within the housing. The lead terminal has a pad disposed in the housing. The housing has a first surface that is joined to the pad, and a second surface that is joined to the substrate with an adhesive agent, the second surface facing in a direction opposite to the first surface. The inner peripheral surface of the housing has a groove that extends over the entire range from the first surface to the second surface, the groove extending from the substrate toward the pad.

A manufacturing method for a semiconductor module according to another aspect of the present disclosure is a method of manufacturing a semiconductor module that includes: a substrate for mounting a semiconductor element; a frame-shaped housing made from a resin composition, the housing surrounding the substrate; a lead terminal that passes through the housing from an inside to an outside; and a bonding wire configured to electrically connect the semiconductor element to the lead terminal within the housing. The method includes: molding the housing by insert molding integrally with a lead frame including the lead terminal; and joining the substrate and the housing to each other with an adhesive agent. The lead terminal has a pad disposed in the housing. The housing has a first surface that is joined to the pad, and a second surface that is joined to the substrate with the adhesive agent, the second surface facing in a direction opposite to the first surface. The inner peripheral surface of the housing has a groove that extends over the entire range from the first surface to the second surface, the groove extending from the substrate toward the pad.

### BRIEF DESCRIPTION OF THE DRAWINGS

FIG. 1 is a plan view of a semiconductor module according to an embodiment;

FIG. 2 is a sectional view taken along line A-A of FIG. 1;

FIG. 3 is a bottom view of the semiconductor module according to the embodiment;

FIG. 4 is a bottom view of a housing;

FIG. 5 is a diagram illustrating a state of the housing and a substrate joined together;

FIG. 6 is a flowchart illustrating a method of manufacturing the semiconductor module according to the embodiment;

FIG. 7 is a diagram illustrating a disposing step in a molding step;

FIG. 8 is a diagram illustrating an injecting step in the molding step;

FIG. 9 is a diagram illustrating a solidifying step in the molding step;

FIG. 10 is a diagram illustrating a mold releasing step in the molding step;

FIG. 11 is a diagram illustrating a joining step;

FIG. 12 is a diagram illustrating a mounting step; and

FIG. 13 is a diagram illustrating a bonding step.

### DESCRIPTION OF THE EMBODIMENTS

Preferred embodiments of the present disclosure will be described below with reference to the drawings. The dimensions and scales of parts in the drawings may differ from the actual as appropriate, and some portions are schematically illustrated for ease of understanding. The scope of the present disclosure is not limited to these forms unless specified in the following description to limit the present disclosure.

### 1. EMBODIMENT

### 1-1. Overall Configuration of Semiconductor Module

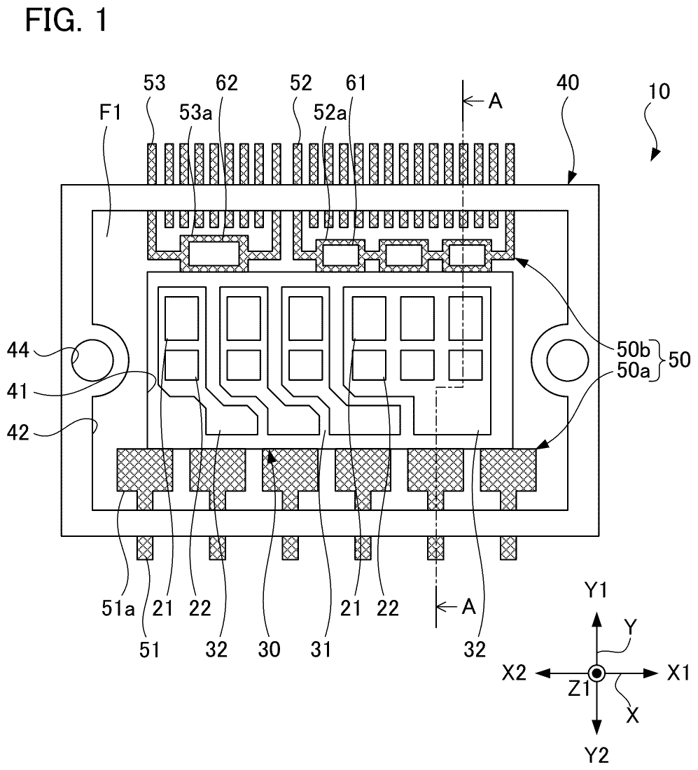

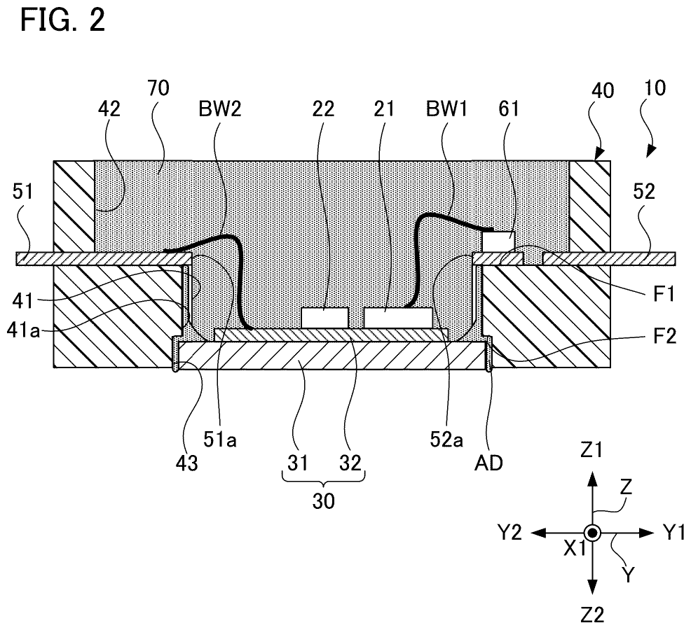

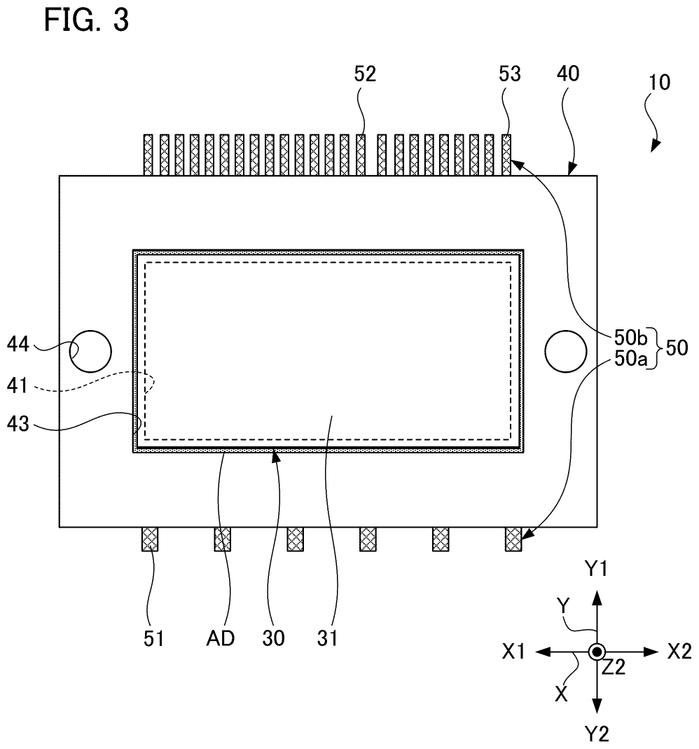

FIG. 1 is a plan view of a semiconductor module 10 according to an embodiment. FIG. 2 is a sectional view taken along line A-A of FIG. 1. FIG. 3 is a bottom view of the semiconductor module 10 according to the embodiment. The semiconductor module 10 is a power module such as an insulated gate bipolar transistor (IGBT) module. In the example illustrated in FIGS. 1 to 3, the semiconductor module 10 is an intelligent power module (IPM) with a built-in inverter bridge circuit and a control circuit. The semiconductor module 10 is used for power control in devices such as inverters or rectifiers mounted in equipment such as air conditioners, railcars, automobiles, or household electrical machinery, for example.

As illustrated in FIGS. 1 to 3, the semiconductor module 10 includes a plurality of semiconductor elements 21, a plurality of semiconductor elements 22, a substrate 30, a housing 40, a terminal group 50 including lead terminals 51, 52, 53, a plurality of electronic components 61, an electronic component 62, bonding wires BW1 and BW2, and a sealing resin 70. In FIG. 1, the sealing resin 70 is omitted for convenience of explanation. In FIGS. 1 and 3, the terminal group 50 is shaded for ease of viewing.

A brief overview of the parts of the semiconductor module 10 will be sequentially provided based on FIGS. 1 to 3. The following explanation will be based on mutually orthogonal X, Y, and Z axes as appropriate for convenience. The Z axis is parallel to the thickness direction of the semiconductor module 10. In the following, one direction along the X axis is an X1 direction, and the direction opposite to the X1 direction is an X2 direction. One direction along the Y axis is a Y1 direction, and the direction opposite to the Y1 direction is a Y2 direction. One direction along the Z axis is a Z1 direction, and the direction opposite to the Z1 direction is a Z2 direction. The relationships between these directions and the vertical direction are not particularly limited, and any relationship is possible. In the following, viewing in the direction along the Z axis is sometimes referred to as “in plan view”. The bottom view is a plan view as seen from the Z2 direction.

The semiconductor element 21 is a switching element such as an IGBT or a power metal-oxide-semiconductor field-effect transistor (MOSFET). An input electrode, which is a drain electrode or a collector electrode, is provided on a bottom surface of the semiconductor element 21, where the bottom surface refers to the side viewed from the Z2 direction. An output electrode, which is a source electrode or an emitter electrode, and a control electrode, which is a gate electrode, are provided on the top surface of the semiconductor element 21, where the top surface refers to the side viewed from the Z1 direction.

The semiconductor element 22 is a diode such as a freewheeling diode (FWD). An output electrode, which is a cathode electrode, is provided on a bottom surface of the semiconductor element 22, where the bottom surface refers to the side viewed from the Z2 direction. An input electrode, which is an anode electrode, is provided on a top surface of the semiconductor element 22, where the top surface refers to the side viewed from the Z1 direction.

In the example illustrated in FIG. 1, a semiconductor element 21 and a semiconductor element 22 are paired with each other, and there are six pairs. The six pairs of the semiconductor elements 21 and the semiconductor elements 22 constitute three sets of half-bridge circuits. The output electrode of the semiconductor element 21 is electrically connected to the input electrode of the paired semiconductor element 22 through bonding wire (not illustrated). The number of the semiconductor elements 21 and the number of the semiconductor elements 22 are not limited to the example illustrated in FIG. 1, and it may be any number. The semiconductor element 21 may be a semiconductor element, such as a reverse-conducting (RC)-IGBT that has both IGBT and FWD functions. In this case, the semiconductor element 22 may be omitted.

The substrate 30 is, for example, a direct copper bonding (DCB) substrate or direct bonded aluminum (DBA) substrate to mount the semiconductor elements 21 and the semiconductor elements 22. The substrate 30 has an insulating substrate 31 and a conductor pattern 32 provided on the top surface of the insulating substrate 31.

The insulating substrate 31 is made from a ceramic, such as aluminum nitride, aluminum oxide, or silicon nitride. The conductor pattern 32 is made from metal, such as copper or aluminum. In the example illustrated in FIG. 1, the conductor pattern 32 is divided into four portions. To each of three of the four portions, the bottom surfaces of a pair of the semiconductor element 21 and the semiconductor element 22 are joined by solder or other conductive bonding material. To the remaining one of the four portions, the bottom surfaces of three pairs of the semiconductor element 21 and the semiconductor element 22 are joined by solder or other conductive bonding material. The shape of the conductor pattern 32 illustrated in FIG. 1 is merely an example, and the shape is not limited thereto. A metal plate may be provided on the bottom surface of the insulating substrate 31. The metal plate is made from the same material as the conductor pattern 32, for example, and has the function of dissipating heat from the semiconductor elements 21 and the semiconductor elements 22.

The housing 40 is a frame-shaped member that surrounds the substrate 30, and houses therein the semiconductor elements 21 and the semiconductor elements 22 mounted on the substrate 30. In the example illustrated in FIG. 1, the housing 40 houses therein the electronic components 61 and the electronic component 62, as well as the semiconductor elements 21 and the semiconductor elements 22.

The housing 40 has an opening 41 that surrounds the semiconductor elements 21 and the semiconductor elements 22 in plan view. As illustrated in FIG. 2, the housing 40 has a recess 42 that opens toward the Z1 direction and a recess 43 that opens toward the Z2 direction. The opening 41 extends from an inner bottom surface of the recess 42 to an inner bottom surface of the recess 43.

The inner bottom surface of the recess 42 comprises a first surface F1. A portion of the terminal group 50 is joined to the first surface F1. The inner bottom surface of the recess 43 comprises a second surface F2. The substrate 30 is joined to the second surface F2 with an adhesive agent AD. At least a portion of the substrate 30 in the thickness direction is disposed in the recess 43. The shapes of the opening 41 and the recesses 42 and 43 are not limited to the example illustrated in FIGS. 1 to 3. For example, the opening 41 and the recesses 42 and 43 may take a shape other than a rectangle in plan view. The opening 41 and the recesses 42 and 43 may be stepped or tapered.

The adhesive agent AD is an epoxy or silicone adhesive agent, for example. The constituent material of the adhesive agent AD may be the same material as the sealing resin 70. In this case, the cost can be reduced compared with a configuration in which the constituent material of the adhesive agent AD is different from that of the sealing resin 70. Moreover, the adhesion between the adhesive agent AD and the sealing resin 70 can advantageously be easily improved.

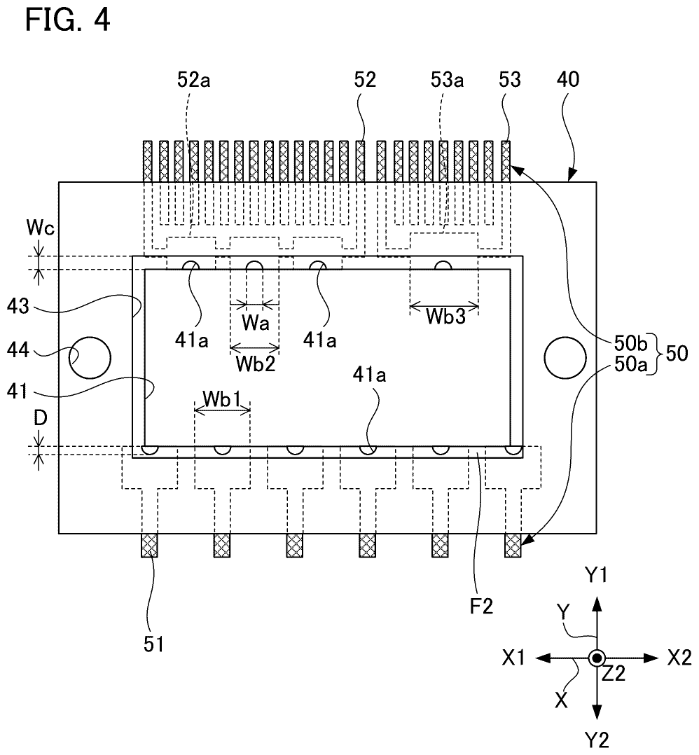

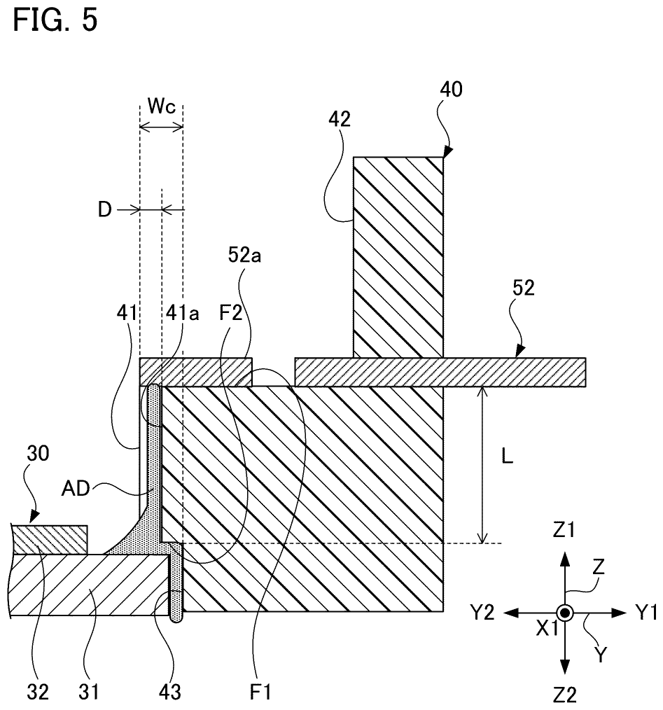

The inner peripheral surface of the opening 41 is provided with a plurality of grooves 41a spaced from each other in the circumferential direction of the opening 41. Each groove 41a extends in the thickness direction (Z direction) of the housing 40, and extends over the entire range from the first surface F1 to the second surface F2. This allows a part of the adhesive agent AD to reach the first surface F1 through the grooves 41a when the substrate 30 and the housing 40 are bonded to each other with the adhesive agent AD. As a result, even if a gap between the first surface F1 and pads 51a, 52a, 53a (described later) is formed during molding of the housing 40, the gap can be filled with a portion of the adhesive agent AD. This ensures that the pads 51a, 52a, 53a and the first surface F1 can be joined without the need for a separate step. The details of the grooves 41a will be described later based on FIGS. 4 and 5.

The housing 40 is a substantial insulator, and is made from a resin composition including a thermoplastic resin, such as polyphenylene sulfide (PPS) or polybutylene terephthalate (PBT). The resin composition may contain inorganic fillers such as alumina or silica from the viewpoint of improving the mechanical strength or thermal conductivity of the housing 40. The housing 40 that is made from the resin composition is molded integrally with the terminal group 50 by insert molding.

The resin used in the resin composition is not limited to a thermoplastic resin, and it may also be a thermosetting resin. However, the housing 40 is preferably made from a resin composition including a thermoplastic resin from the viewpoint of forming the housing 40 integrally with the lead terminals 51, 52, 53 by insert molding in a simple and precise manner. Thermoplastic resins generally have excellent moldability, but poor contact with metals. Thus, when the housing 40 is made from a resin composition including a thermoplastic resin, a gap is likely to form between the housing 40 and the pads 51a, 52a, 53a after insert molding. Accordingly, the effect of the present disclosure is pronounced.

The terminal group 50 is a set of a plurality of leads for electrically connecting each of the semiconductor elements 21 and 22 and the electronic components 61 and 62 to a substrate (not illustrated) on which the semiconductor module 10 is mounted. Each of the lead terminals constituting the terminal group 50 has a portion that is disposed on the inner bottom surface of the recess 42, and passes through the housing 40 from an inside to an outside of the housing 40. The terminal group 50 is made from a metal, such as copper, a copper alloy, aluminum, an aluminum alloy, or an iron alloy, and is obtained by machining lead frames.

The terminal group 50 is divided into two groups: a terminal group 50a made up of a plurality of the lead terminals 51 for main current; and a terminal group 50b made up of a plurality of lead terminals including the lead terminals 52 and 53 for control signals.

The lead terminals 51 constituting the terminal group 50a include a high potential side lead terminal, a low potential side lead terminal, and an output lead terminal. The lead terminals 51 each has a pad 51a that is joined to the first surface F1 of the housing 40 described above. As illustrated in FIG. 2, one end of the bonding wire BW2 is joined to the pad 51a. The other end of the bonding wire BW2 is bonded to the conductor pattern 32 of the substrate 30. In this manner, the bonding wire BW2 electrically connects the semiconductor elements 21 and 22 to the lead terminals 51 in the housing 40. The shape, arrangement, and number of the leads constituting the terminal group 50a are not limited to the example illustrated in FIG. 1.

The lead terminals constituting the terminal group 50b includes lead terminals 52 and 53. The lead terminal 52 has a plurality of pads 52a that are joined to the first surface F1 of the housing 40 described above. The electronic component 61 is joined to each pad 52a by solder or other conductive bonding material (not illustrated). The lead terminal 53 has a pad 53a that is joined to the first surface F1 of the housing 40 described above. The electronic component 62 is joined to the pad 53a by solder or other conductive bonding material (not illustrated).

The above terminal group 50 is integrated with the housing 40 by insert molding. Thus, the lead terminals 51, 52, and 53 are joined to the housing 40 by insert molding. This reduces the difficulty in filling the gap formed between the housing 40 and portions other than the pads 51a, 52a, 53a of the lead terminals 51, 52, 53 with the adhesive agent AD, compared with a configuration in which the lead terminals 51, 52, 53 are incorporated into the housing 40 after the housing 40 is molded. Even if a gap is formed between the housing 40 and the pads 51a, 52a, 53a, when the housing 40 and the substrate 30 are joined to each other with the adhesive agent AD, a portion of the adhesive agent AD can be smoothly supplied to the gap from between the housing 40 and the substrate 30 through the grooves 41a. In this case, because the gap is of a size that allows capillary action of the adhesive agent AD to occur before curing, the gap can be suitably filled with the adhesive agent AD.

The electronic components 61 and 62 are electronic components such as integrated circuits (ICs) to drive the semiconductor elements 21. In the example illustrated in FIG. 1, three electronic components 61 correspond to three semiconductor elements 21 among the six semiconductor elements 21, and one electronic component 62 corresponds to the remaining three semiconductor elements 21. As illustrated in FIG. 2, one end of the bonding wire BW1 is joined to a control electrode of the electronic component 61. The other end of the bonding wire BW1 is joined to a control electrode of the semiconductor element 21. In this manner, the bonding wire BW1 electrically connects the semiconductor elements 21 to the lead terminals 52 within the housing 40. One end of a bonding wire (not illustrated) is joined to a control electrode of the electronic component 62. The other end of this bonding wire is joined to the control electrode of the semiconductor element 21. In addition to the electronic components 61 and 62, an electronic component such as a boot strap diode (BSD) or other diodes may be mounted on the terminal group 50b.

The sealing resin 70 is a potting material with which the housing 40 is filled. The sealing resin 70 is made from a thermosetting resin such as an epoxy resin or silicone resin. The sealing resin 70 preferably contains inorganic fillers such as silica or alumina from the viewpoint of increasing thermal conductivity. The sealing resin 70 may be in gel form.

### 1-2. Inner Peripheral Surface of Housing

FIG. 4 is a bottom view of the housing 40. FIG. 5 is a diagram illustrating the state of joining the housing 40 and the substrate 30. FIG. 4 illustrates a view of the housing 40 that is formed integrally with the terminal group 50, as seen in the Z1 direction. FIG. 5 illustrates a portion of the cross section illustrated in FIG. 2. In FIG. 5, the electronic components 61, the sealing resin 70, and the bonding wires BW1 are omitted for ease of explanation.

As illustrated in FIG. 4, the inner peripheral surface of the opening 41 of the housing 40 is provided with the grooves 41a spaced from each other in the circumferential direction of the opening 41. In the example illustrated in FIG. 4, the grooves 41a are provided corresponding to the pads 51a, 52a, 53a. Each groove 41a overlaps one of the pads 51a, 52a, and 53a in plan view. Thus, the grooves 41a include grooves 41a that overlap the pads 51a in plan view, grooves 41a that overlap the pads 52a in plan view, and a groove 41a that overlaps the pad 53a in plan view. This allows the adhesive agent AD, before solidification, to suitably move through the grooves 41a toward the pads 51a, 52a, 53a, as described later.

The pads 51a, 52a, 53a are each rectangular in plan view, with sides that are substantially aligned with the inner peripheral surface of the opening 41. According to this configuration, compared with a configuration in which the pads 51a, 52a, 53a have portions that are located inside the inner peripheral surface of the opening 41 in plan view, an advantage is obtained in that reduction in size of the semiconductor module 10 is facilitated and routing of the bonding wires BW1 and BW2 is facilitated when the wires are joined to the electronic components 61 and 62 and the lead terminals 52. This also allows the adhesive agent AD before solidification to suitably move through the grooves 41a toward the pads 51a, 52a, 53a, as described later, compared with a configuration in which a gap exists between each of the pads 51a, 52a, 53a and the opening 41 in plan view.

A width Wa of the groove 41a corresponding to the pad 51a in the longitudinal direction (in the X direction) of the housing 40 is smaller than a width Wb1 of the pad 51a in the longitudinal direction (in the X direction) of the housing 40. The width Wa of the groove 41a corresponding to the pad 52a is smaller than a width Wb2 of the pad 52a in the longitudinal direction (in the X direction) of the housing 40. The width Wa of the groove 41a corresponding to the pad 53a in the longitudinal direction is smaller than a width Wb3 of the pad 53a in the longitudinal direction (in the X direction) of the housing 40.

In this manner, the width Wa of the groove 41a is smaller than the widths Wb1, Wb2, Wb3 of the pads 51a, 52a, 53a. This allows a portion of the adhesive agent AD between the housing 40 and the substrate 30 to be smoothly supplied between the pads 51a, 52a, 53a and the housing 40 through the grooves 41a without excessive use of the adhesive agent AD to join the substrate 30 and the housing 40 to each other.

In the example illustrated in FIG. 4, each of the plurality of widths Wa of the grooves 41a is equal to the others. Thus, the width Wa of each groove 41a is smaller than the width Wb1, the width Wb2, and the width Wb3. The width Wa of each groove 41a is constant between the first surface F1 and the second surface F2. The widths Wa of the grooves 41a may differ from each other. The number of the grooves 41a corresponding to each pad 51a, each pad 52a, or the pad 53a may be two or more. The width Wa of the groove 41a may decrease from the second surface F2 toward the first surface F1.

The width Wa of the groove 41a is preferably from 0.1 to 0.5 times the width Wb1, the width Wb2, or the width Wb3, and is more preferably from 0.2 to 0.4 times the width Wb1, the width Wb2, or the width Wb3. This allows the adhesive agent AD before solidification to suitably move through the grooves 41a toward the pads 51a, 52a, 53a, as described later. In contrast to this, if the width Wa is too large, the amount of the adhesive agent AD required for moving through the grooves 41a toward the pads 51a, 52a, 53a tends to be excessive, or the adhesive agent AD tends to easily penetrate to undesired areas, as described later. On the other hand, if the width Wa is too small, depending on the size of the gap between the pads 51a, 52a, 53a and the first surface F1, it is difficult to sufficiently fill the gap with the adhesive agent AD.

Depth D of the groove 41a is less than width Wc of the second surface F2. The width Wc is a distance between the inner peripheral surface of the opening 41 and a side of the recess 43. The depth D of the groove 41a is preferably from 0.2 to 0.8 times the width Wa of the groove 41a, and is more preferably from 0.3 to 0.7 times the width Wa, and is even more preferably from 0.4 to 0.6 times the width Wa. This allows the adhesive agent AD, before solidification, to suitably penetrate through the grooves 41a toward the pads 51a, 52a, 53a, as described later. In contrast to this, if the depth D is too large, the amount of the adhesive agent AD required for penetrating through the grooves 41a toward the pads 51a, 52a, 53a tends to be excessive, as described later. On the other hand, if the depth D is too small, depending on the size of the gap between the pads 51a, 52a, 53a and the first surface F1, it is difficult to sufficiently fill the gap with the adhesive agent AD.

Each groove 41a has a cross-sectional shape, the width of which decreases toward the bottom of the groove 41a in the depth direction (Y direction). In other words, this allows the adhesive agent AD to easily move along the grooves 41a. In the example illustrated in FIG. 4, the groove 41a is a U-shaped groove. The depth D of the groove 41a is constant between the first surface F1 and the second surface F2. The cross-sectional shape of the groove 41a is not limited to the example illustrated in FIG. 4, and any shape is possible. For example, the groove 41a may be a V-shaped groove. The groove 41a may be shaped with a decreasing depth D from the second surface F2 toward the first surface F1.

As illustrated in FIG. 5, the housing 40 has the first surface F1 and the second surface F2 facing in the direction opposite to the first surface F1. The first surface F1 has the pads 51a, 52a, 53a joined thereto. The substrate 30 is joined to the second surface F2 with the adhesive agent AD. In FIG. 5, the pad 52a is illustrated as a representative of the pads 51a, 52a, 53a. However, the relationships between the pads 51a, 53a and the groove 41a are the same as that between the pad 52a and the groove 41a.

The groove 41a extends from the substrate 30 toward the pad 51a, the pad 52a, or the pad 53a, and extends over the entire range from the first surface F1 to the second surface F2. According to this configuration, when the housing 40 and the substrate 30 are joined to each other with the adhesive agent AD, it is possible to smoothly supply a portion of the adhesive agent AD from between the housing 40 and the substrate 30 through the grooves 41a to the gap.

### 1-3. Manufacturing Method for Semiconductor Module

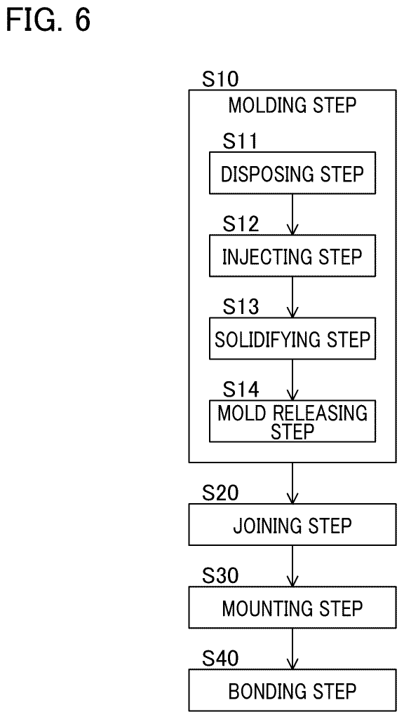

FIG. 6 is a flowchart illustrating a method of manufacturing the semiconductor module 10 according to an embodiment. The method of manufacturing the semiconductor module 10 includes a molding step S10, a joining step S20, a mounting step S30, and a bonding step S40, in this order, as illustrated in FIG. 6.

In the molding step S10, the housing 40 is formed by insert molding integrally with a lead frame 500 including the lead terminals 51, 52, 53. Specifically, the molding step S10 includes a disposing step S11, an injecting step S12, a solidifying step S13, and a mold releasing step S14, in this order.

In the disposing step S11, the lead frame 500 is disposed into a mold 100. In the injecting step S12, a resin composition is injected into the mold 100. In the solidifying step S13, the resin composition in the mold 100 is solidified to obtain the housing 40. In the mold releasing step S14, the housing 40 is removed from the mold 100.

In the joining step S20, the substrate 30 and the housing 40 are joined to each other with the adhesive agent AD. In the mounting step S30, the semiconductor elements 21 and 22 are mounted on the substrate 30, and the electronic components 61 and 62 are mounted on the lead frame 500. In the bonding step S40, the bonding wires BW1 and BW2 are formed. Although not illustrated, the sealing resin 70 is formed after the bonding step S40. Also, after the molding step S10, unnecessary parts of the lead frame 500 are removed at freely-selected times. As a result, the terminal group 50 is obtained. As a result of the above process, the semiconductor module 10 is obtained. Each of the steps will be described in detail in turn below.

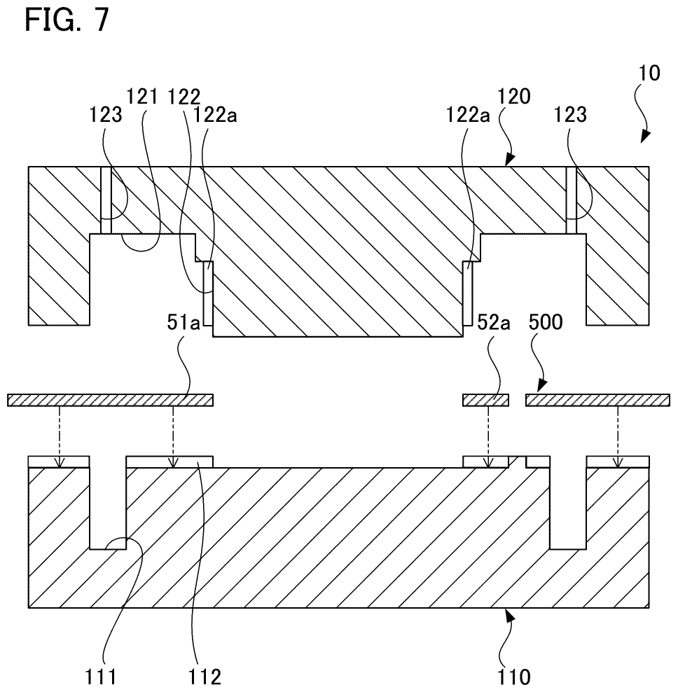

FIG. 7 is a diagram illustrating the disposing step S11 in the molding step S10. In the disposing step S11, the lead frame 500 is disposed into the mold 100, as illustrated in FIG. 7.

The lead frame 500 is made up of the terminal group 50 and portions other than the terminal group 50. The portions of the lead frame 500 other than the terminal group 50 are removed at freely-selected times after the molding step S10.

The mold 100 has a lower mold 110 and an upper mold 120. The lower mold 110 has a molding surface 111 that molds the top surface of the housing 40. The molding surface 111 is provided with a recess 112. In the disposing step S11, the lead frame 500 is disposed on the molding surface 111 with the lead frame 500 fitted into the recess 112. The upper mold 120 has a molding surface 121 that molds an outer bottom surface of the housing 40, a molding surface 122 that molds the inner wall of the opening 41, and a plurality of gates 123 to inject a resin composition RC, which will be described later, into the mold 100. The molding surface 122 is provided with a plurality of projections 122a to form the grooves 41a.

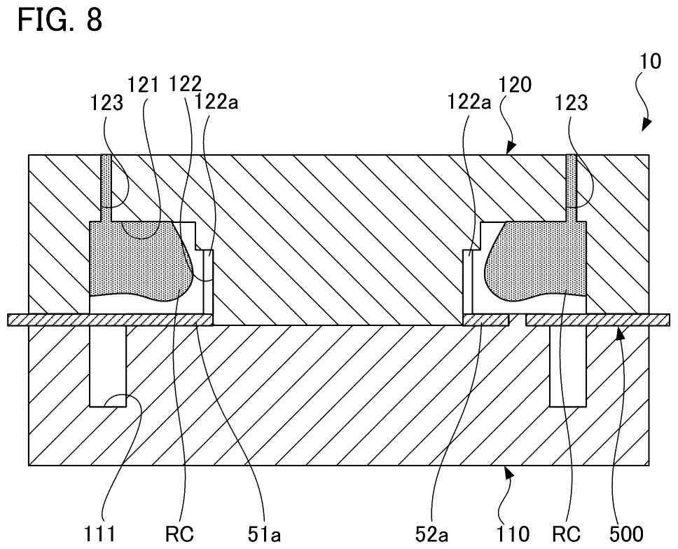

FIG. 8 is a diagram illustrating the injecting step S12 in the molding step S10. In the injecting step S12, the mold 100 is closed, and then, in that state, the aforementioned resin composition RC, while softened by the application of heat, is injected into the mold 100, as illustrated in FIG. 8. At this time, the pads 51a, 52a, 53a of the lead frame 500 are held down toward the lower mold 110 by the projections 122a.

Fixed pins or movable pins could be provided in the upper mold 120 as a method to hold down the pads 51a, 52a, 53a toward the lower mold 110. However, in the method using the fixing pins, holes are formed in the housing 40 by the fixing pins, so that a step to fill the holes after the molding step S10 is necessary, separate from the joining step S20. In the method using the movable pins, the movable pins are retracted before the solidifying step S13, resulting in misalignment of the pads 51a, 52a, 53a.

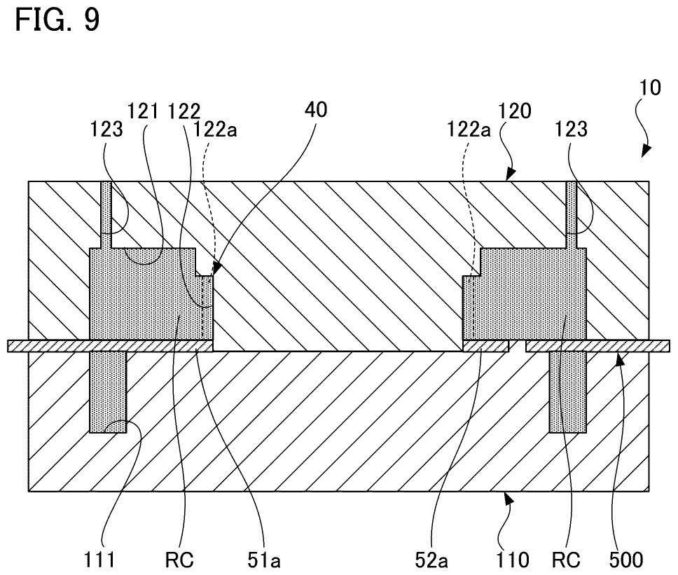

FIG. 9 is a diagram illustrating the solidifying step S13 in the molding step S10. In the solidifying step S13, the mold 100 is filled with the resin composition RC, and then the resin composition RC in the mold 100 is cooled to a temperature lower than the softening point, as illustrated in FIG. 9. This solidifies the resin composition RC, resulting in the housing 40 integrated with the lead frame 500.

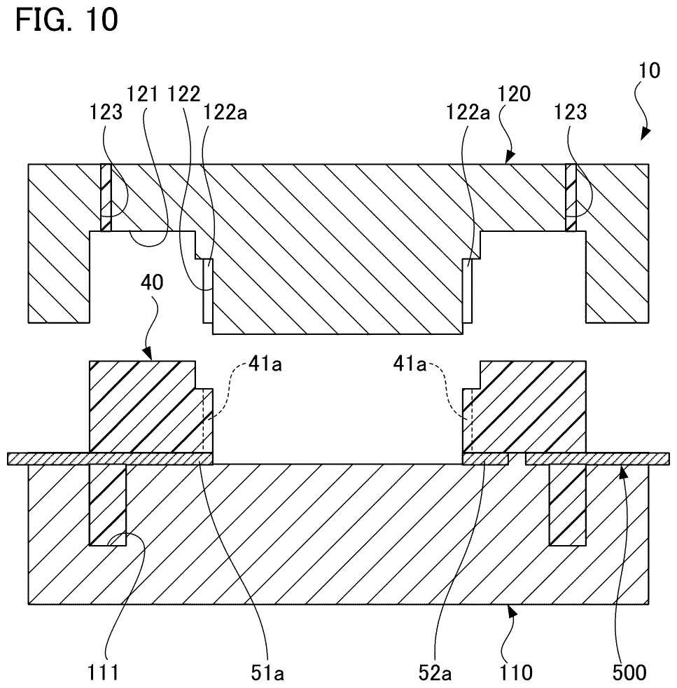

FIG. 10 is a diagram illustrating the mold releasing step S14 in the molding step S10. In the mold releasing step S14, the mold 100 is opened, and then the housing 40 is removed from the mold 100, as illustrated in FIG. 10.

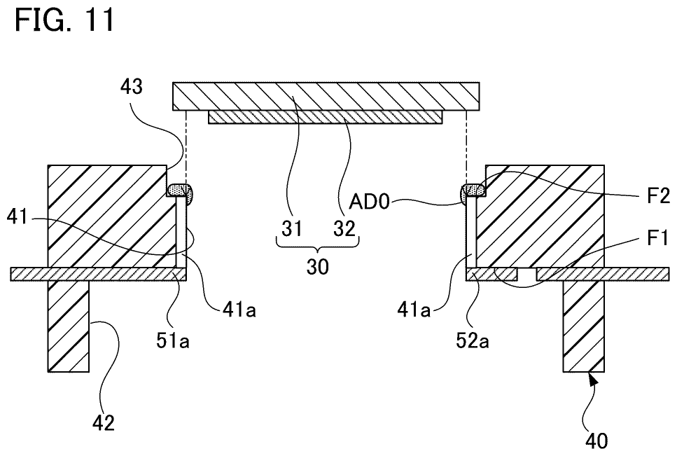

FIG. 11 is a diagram illustrating the joining step S20. In the joining step S20, an adhesive agent AD0 is applied around the periphery of the second surface F2 of the recess 43, and then the substrate 30 is inserted into the recess 43 of the housing 40, as illustrated in FIG. 11. As a result, the substrate 30 is joined to the housing 40 with the adhesive agent AD0. The adhesive agent AD0 is the adhesive agent AD before curing and becomes the adhesive agent AD upon curing. A portion of the adhesive agent AD0 reaches the first surface F1 along the groove 41a from the second surface F2 as the substrate 30 is inserted into the recess 43 of the housing 40 in the joining step S20.

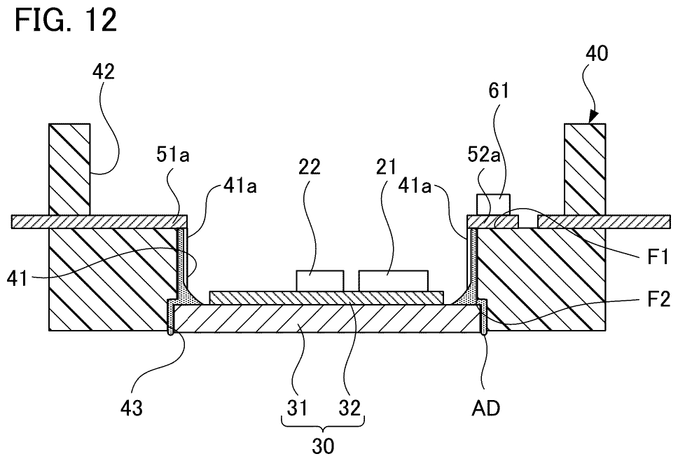

FIG. 12 is a diagram illustrating the mounting step S30. In the mounting step S30, the semiconductor elements 21 and 22 are joined to the conductor pattern 32 of the substrate 30 by solder or other conductive bonding material, and the electronic components 61 and 62 are joined to the pads 52a and 53a of the lead frame 500, as illustrated in FIG. 12. As a result, the semiconductor elements 21 and 22 are mounted on the substrate 30, and the electronic components 61 and 62 are mounted on the lead frame 500.

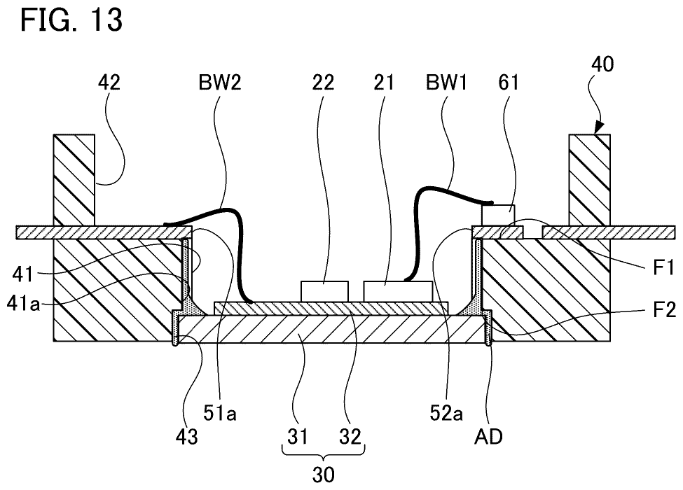

FIG. 13 is a diagram illustrating the bonding step S40. In the bonding step S40, bonding wires BW1 and BW2 are formed, as illustrated in FIG. 13. In the bonding step S40, one end of the bonding wire BW1 is ultrasonically joined to the control electrode on the top surface of the electronic component 61, and the other end of the bonding wire BW1 is ultrasonically joined to the control electrode on the top surface of the semiconductor element 21. In the bonding step S40, one end of the bonding wire BW2 is ultrasonically joined to the pad 51a, and the other end of the bonding wire BW2 is ultrasonically joined to the conductor pattern 32 of the substrate 30.

As described above, the method of manufacturing the semiconductor module 10 includes the molding step S10 and the joining step S20. In the molding step S10, the housing 40 is formed by insert molding integrally with the lead frame 500 including the lead terminals 51, 52, 53. In the joining step S20, the substrate 30 and the housing 40 are joined to each other with the adhesive agent AD.

In the manufacturing method described above, the inner peripheral surface of the housing 40 is provided with the grooves 41a that extend over the entire range from the first surface F1 to the second surface F2, the grooves 41a extending from the substrate 30 toward the pads 51a, 52a, 53a. Therefore, even if a gap forms between the pads 51a, 52a, 53a and the housing 40, when the housing 40 and the substrate 30 are joined to each other with the adhesive agent AD, a portion of the adhesive agent AD can be smoothly supplied from between the housing 40 and the substrate 30 through the grooves 41a to the gap. Accordingly, even if a gap is formed between the pads 51a, 52a, 53a and the housing 40, it is possible to join the pads 51a, 52a, 53a to the housing 40 with the adhesive agent AD without the need for a separate step. As a result, a semiconductor module 10 with excellent reliability can be easily manufactured.

In the molding step S10, the mold 100 having the projections 122a corresponding to the grooves 41a are used to form the grooves 41a, as described above. Thus, the molding step S10 can provide the grooves 41a that extend over the entire range from the first surface F1 to the second surface F2 on the inner peripheral surface of the housing 40. In the molding step S10, as a result of the projections 122a reaching the first surface F1, the pads 51a, 52a, 53a are held down by the projections 122a, as described above. This allows the lead terminals 51, 52, 53 to be fixed, so as to be disposed in desired positions of the housing 40. Moreover, holes are not formed in the housing 40, as in a configuration in which fixing pins are provided in the mold 100. Thus, a step to fill the holes is not necessary, and the reliability of the housing 40 is not reduced due to the holes.

The method of manufacturing the semiconductor module 10 includes the bonding step S40, as described above. In the bonding step S40, after the joining step S20, the bonding wire BW2 is joined to the pad 51a, and the bonding wires Bwl are joined to the electronic components 61 on the pad 52a and the electronic component 62 on the pad 53a. Because the aforementioned joining step S20 ensures that the pads 51a, 52a, 53a are joined to the housing 40, in the bonding step S40, the bonding wire BW2 can be suitably joined to the pad 51a, and the bonding wires BW1 to the electronic components 61 on the pad 52a and the electronic component 62 on the pad 53a.

In the semiconductor module 10 described above, the inner peripheral surface of the housing 40 is provided with the grooves 41a that extend over the entire range from the first surface F1 to the second surface F2, the grooves 41a extending from the substrate 30 toward the pads 51a, 52a, 53a. Therefore, even if a gap forms between the pads 51a, 52a, 53a and the housing 40, when the housing 40 and the substrate 30 are joined to each other with the adhesive agent AD, a portion of the adhesive agent AD can be smoothly supplied from between the housing 40 and the substrate 30 through the grooves 41a to the gap. Thus, even if a gap is formed between the pads 51a, 52a, 53a and the housing 40, it is possible to join the pads 51a, 52a, 53a with the housing 40 with the adhesive agent AD without the need for a separate step. As a result, a semiconductor module 10 with excellent reliability can be easily manufactured.

### 2. MODIFICATIONS

The present disclosure is not limited to the aforementioned embodiments, and various modifications described below can be made. The embodiments and modifications may be combined as appropriate.

### 2-1. First Modification

In the aforementioned embodiment, the semiconductor module 10 is an IPM having the electronic components 61 and 62. However, the embodiment is not limited thereto, and the electronic components 61 and 62 may be omitted, for example. In this case, the bonding wires BW1 are joined to the pads 52a and 53a.

### 2-2. Second Modification

In the aforementioned embodiment, the electronic components 61 and 62 are mounted on the terminal group 50. However, the embodiment is not limited thereto, and the electronic components 61 and 62 may be mounted on the substrate 30 as semiconductor elements.

### 3. APPENDICES

For example, the following aspects are derivable from the embodiments or modifications described above.

### Appendix 1

A semiconductor module according to a first aspect, which is an example of the present disclosure includes: a substrate for mounting a semiconductor element; a frame-shaped housing that surrounds the substrate; a lead terminal that passes through the housing from an inside to an outside of the housing; and a bonding wire configured to electrically connect the semiconductor element to the lead terminal within the housing. The lead terminal has a pad disposed in the housing. The housing has a first surface that is joined to the pad, and a second surface that is joined to the substrate with an adhesive agent, the second surface facing in a direction opposite to the first surface. The inner peripheral surface of the housing has a groove that extends over the entire range from the first surface to the second surface, the groove extending from the substrate toward the pad.

In the above aspect, the groove is provided on the inner peripheral surface of the housing, the groove extending over the entire range from the first surface to the second surface and extending from the substrate toward the pad. Therefore, even if a gap is formed between the pad and the housing, when the housing and the substrate are joined to each other by the adhesive agent, a portion of the adhesive agent can be smoothly supplied from between the housing and the substrate through the groove to the gap. Even if a gap forms between the pad and the housing, this allows the pad and the housing to be joined to each other with the adhesive agent without the need for a separate step. As a result, a semiconductor module with excellent reliability can be easily manufactured.

### Appendix 2

In the semiconductor module according to a second aspect, which is an example of the first aspect, the groove has a cross-sectional shape a width of which decreases toward the bottom of the groove. The above aspect allows the adhesive agent to easily move along the groove.

### Appendix 3

In the semiconductor module according to a third aspect, which is an example of the first or second aspect, a width of the groove is smaller than a width of the pad. The above aspect allows a portion of the adhesive agent between the housing and the substrate to be smoothly supplied between the pad and the housing through the groove without excessive use of the adhesive agent to join the substrate and the housing to each other.

### Appendix 4

In the semiconductor module according to a fourth aspect, which is an example of any one of the first to third aspects, the lead terminal is joined to the housing by insert molding. The above aspect reduces the difficulty in filling the gap formed between the housing and portions other than the pad of the lead terminal with the adhesive agent compared with a configuration in which the lead terminal is incorporated into the housing after the housing is molded. Even if a gap is formed between the housing and the pad, when the housing and the substrate are joined to each other with the adhesive agent, a portion of the adhesive agent can be smoothly supplied from between the housing and the substrate through the groove to the gap. Furthermore, because the gap is of a degree that it allows capillary action for the adhesive agent to occur before curing, the gap can be suitably filled with the adhesive agent.

### Appendix 5

In the semiconductor module according to a fifth aspect, which is an example of any one of the first to fourth aspects, the housing is made from a resin composition including a thermoplastic resin. The above aspect allows the housing to be formed integrally with the lead terminal by insert molding in a simple and precise manner. Thermoplastic resins generally have excellent moldability, but poor contact with metals. Thus, when the housing is made from a resin composition including a thermoplastic resin, a gap is likely to be formed between the housing and the pad after insert molding, so that the effect of the present disclosure is pronounced.

### Appendix 6

A manufacturing method for a semiconductor module according to a sixth aspect, which is another aspect of the present disclosure, is a method of manufacturing a semiconductor module that includes: a substrate for mounting a semiconductor element; a frame-shaped housing made from a resin composition, the housing surrounding the substrate; a lead terminal that passes through the housing from an inside to an outside; and a bonding wire configured to electrically connect the semiconductor element to the lead terminal within the housing. The method includes: molding the housing by insert molding integrally with a lead frame including the lead terminal; and joining the substrate and the housing to each other with an adhesive agent. The lead terminal has a pad disposed in the housing. The housing has a first surface that is joined to the pad, and a second surface that is joined to the substrate with the adhesive agent, the second surface facing in a direction opposite to the first surface. The inner peripheral surface of the housing has a groove that extends over the entire range from the first surface to the second surface, the groove extending from the substrate toward the pad.

In the above aspect, the groove is provided on the inner peripheral surface of the housing, the groove extending over the entire range from the first surface to the second surface and extending from the substrate toward the pad. Therefore, even if a gap is formed between the pad and the housing, when the housing and the substrate are joined to each other by the adhesive agent, a portion of the adhesive agent can be smoothly supplied from between the housing and the substrate through the groove to the gap. Even if a gap is formed between the pad and the housing, this allows the pad and the housing to be joined to each other with the adhesive agent without the need for a separate step. As a result, a semiconductor module with excellent reliability can be easily manufactured.

### Appendix 7

In the manufacturing method for the semiconductor module according to a seventh aspect, which is an example of the sixth aspect, the molding includes forming the groove using a mold having a projection corresponding to the groove. The above aspect allows the molding to provide the groove that extends over the entire range from the first surface to the second surface on the inner peripheral surface of the housing. The pad of the lead terminal is also held down by the projection in the molding, allowing the lead terminal to be disposed in a desired position of the housing. Moreover, holes are not formed in the housing, in contrast to a configuration in which fixing pins are provided in the mold. Thus, a step to fill the holes is not necessary, and the reliability of the housing is not reduced due to the holes.

### Appendix 8

In the manufacturing method for the semiconductor module according to an eighth aspect, which is an example of the seventh aspect, in the molding, the pad is held down by the projection as a result of the projection reaching the first surface. The above aspect allows the lead terminal to be disposed in a desired position of the housing.

### Appendix 9

The manufacturing method for the semiconductor module according to a ninth aspect, which is an example of any one of the sixth to eighth aspects, further includes bonding the bonding wire to the pad or to an electronic component on the pad after the joining. The above aspect allows the bonding wire to be suitably bonded to the pad or to an electronic component on the pad.

### DESCRIPTION OF REFERENCE SIGNS

10 semiconductor module
21 semiconductor element
22 semiconductor element
30 substrate
31 insulating substrate
32 conductor pattern
40 housing
41 opening
418 groove
42 recess
43 recess
50 terminal group
50a terminal group
50b terminal group
51 lead terminal
51a pad
52 lead terminal
52a pad
53 lead terminal
53a pad
61 electronic component
62 electronic component
70 sealing resin
100 mold
110 lower mold
111 molding surface
112 recess
120 upper mold
121 molding surface
122 molding surface
122a projection
123 gate
500 lead frame
AD adhesive agent
AD0 adhesive agent
BW1 bonding wire
BW2 bonding wire
D depth
F1 first surface
F2 second surface
RC resin composition
S10 molding step
S11 disposing step
S12 injecting step
S13 solidifying step
S14 mold releasing step
S20 joining step
S30 mounting step
S40 bonding step
Wa width
Wb1 width
Wb2 width
Wb3 width
Wc width

What is claimed is:

1. A semiconductor module comprising:
a substrate for mounting a semiconductor element;
a frame-shaped housing that surrounds the substrate;
a lead terminal that passes through the frame-shaped housing from an inside to an outside of the frame-shaped housing; and
a bonding wire configured to electrically connect the semiconductor element to the lead terminal within the frame-shaped housing, wherein
the lead terminal has a pad disposed in the frame-shaped housing, the frame-shaped housing having:
a first surface that is joined to the pad; and
a second surface that is joined to the substrate with an adhesive agent, the second surface facing in a direction opposite to the first surface, and
an inner peripheral surface of the frame-shaped housing having a groove that extends over an entire range from the first surface to the second surface, the groove extending from the substrate toward the pad.

2. The semiconductor module according to claim 1, wherein the groove has a cross-sectional shape a width of which decreases toward a bottom of the groove.

3. The semiconductor module according to claim 1, wherein a width of the groove is smaller than a width of the pad.

4. The semiconductor module according to claim 1, wherein the lead terminal is joined to the frame-shaped housing by insert molding.

5. The semiconductor module according to claim 4, wherein the frame-shaped housing is made from a resin composition including a thermoplastic resin.

6. A manufacturing method for a semiconductor module, wherein the semiconductor module includes:
a substrate for mounting a semiconductor element;
a frame-shaped housing made from a resin composition, the frame-shaped housing surrounding the substrate;
a lead terminal that passes through the frame-shaped housing from an inside to an outside of the frame-shaped housing; and
a bonding wire configured to electrically connect the semiconductor element to the lead terminal within the frame-shaped housing,
the method comprising:
molding the frame-shaped housing by insert molding integrally with a lead frame that includes the lead terminal; and
joining the substrate and the frame-shaped housing to each other with an adhesive agent,
wherein
the lead terminal has a pad disposed in the frame-shaped housing,
the frame-shaped housing has:
a first surface that is joined to the pad; and
a second surface that is joined to the substrate with the adhesive agent, the second surface facing in a direction opposite to the first surface, and
an inner peripheral surface of the frame-shaped housing has a groove that extends over an entire range from the first surface to the second surface, the groove extending from the substrate toward the pad.

7. The manufacturing method for the semiconductor module according to claim 6, wherein the molding includes forming the groove using a mold having a projection corresponding to the groove.

8. The manufacturing method for the semiconductor module according to claim 7, wherein, in the molding, the pad is held down by the projection as a result of the projection reaching the first surface.

9. The manufacturing method for the semiconductor module according to claim 6, further comprising bonding the bonding wire to the pad or to an electronic component on the pad after the joining.
